(19) United States
(12) Patent Application Publication
(10) Pub. No.: US 2018/0024592 A1
(43) Pub. Date: Jan. 25, 2018

(54) HARD COATING FILM AND FLEXIBLE DISPLAY WINDOW INCLUDING TOUCH SENSOR USING THE SAME

(71) Applicant: DONGWOO FINE-CHEM CO., LTD., Iksan-si (KR)

(72) Inventors: Geo San LIM, Seoul (KR); Sung Min KIM, Seoul (KR); Han Young CHOI, Pyeongtaek-si (KR)

(21) Appl. No.: 15/654,794

(22) Filed: Jul. 20, 2017

(30) Foreign Application Priority Data
Jul. 22, 2016 (KR) 10-2016-0093232

(51) Int. Cl. G06F 1/16; H01L 51/56; G06F 3/041

(52) U.S. Cl. CPC G06F 1/1652; G06F 3/0412; H01L 51/56; G06F 2203/04102; G06F 2203/04103

(57) ABSTRACT

The present invention relates to a hard coating film used as a film for a flexible display window including a touch sensor and a flexible display window including a touch sensor using the same, and particularly, to a hard coating film having a surface resistance of 5*10¹¹ Ω/sq to 5*10¹³ Ω/sq.

### CROSS-REFERENCE TO RELATED APPLICATIONS

This U.S. non-provisional patent application claims priority under 35 U.S.C. §119 of Korean Patent Application No. 10-2016-0093232, filed on Jul. 22, 2016 in the Korean Patent Office, the entire contents of which are hereby incorporated by reference.

### FIELD OF INVENTION

The present invention relates to a hard coating film used as a film for a flexible display window comprising a touch sensor, and particularly, to a hard coating film capable of driving a touch sensor, preventing dust adhesion and simultaneously improving surface hardness and bending resistance of a window film, and a flexible display window including a touch sensor using the same.

### BACKGROUND

As mobile devices such as smart phones and tablet PCs have been developed in recent years, thinner and slimmer display substrates have been required. Glass or tempered glass as a material having excellent mechanical properties has been generally used for a display window or a front plate of these mobile devices. However, the glass causes a weight of the mobile devices to be heavy due to its own weight, and has a problem of damage due to an external impact.

Accordingly, plastic resins are being studied as a substitute for glass. A plastic resin composition is appropriate for the trend of pursuing a lighter mobile device because it is lightweight and is less likely to be broken. In particular, in order to achieve a composition capable of touch driving, preventing dust adhesion and having surface resistance, pencil hardness and bending resistance, a composition for being applied as a hard coating layer onto a supporting substrate has been proposed.

Korean Registered Patent No. 10-1241280 relates to a UV-curable hard coating composition having anti-smudge and antistatic properties, which includes 3 to 30 parts by weight of a UV-curable resin, 0.01 to 3 parts by weight of a fluorine-modified multifunctional acrylate compound, 5 to 30 parts by weight of a conductive polymer aqueous solution, 0.1 to 5 parts by weight of a photopolymerization initiator and 30 to 90 parts by weight of a polar organic solvent having affinity for a conductive polymer with respect to 100 parts by weight of the entire composition, and a hard coating layer formed by curing the composition by UV irradiation has a hardness equal to or greater than 3 H, a surface resistance of 10⁶ to 10⁸ Ω/sq, a water contact angle equal to or greater than 95 degrees, a visible light transmittance equal to or greater than 92% and a haze value equal to or greater than 0.5%. Since a hard coating layer having anti-smudge and antistatic properties may be formed on a plastic panel by applying the composition once, the process may be simple, production costs may be low, and excellent adhesion with a plastic panel, transparency, abrasion resistance, antistatic properties and contamination resistance may be exhibited.

In addition, Korean Registered Patent No. 10-0199406 relates to a photocurable hard coating composition having antistatic properties, which consists of 10 to 60 wt % of a hexa-functional acrylic monomer, 4 to 20 wt % of a tri-functional acrylic monomer, 20 to 60 wt % of an acrylic monomer, 3 to 7 wt % of a photoinitiator, 3 to 40 wt % of a UV-curable permanent antistatic agent, 0 to 10 wt % of conductive titania and a small amount of a UV stabilizer, and a method of applying the same. The composition imparts antistatic properties to a coating film and simultaneously is effective in improving properties such as scratch resistance, abrasion resistance, weather resistance, contamination resistance, slipperiness and the like.

However, the conventional technologies may have a problem in touch driving due to low surface resistance, and it may be difficult to apply them to a flexible display including a touch sensor due to a decrease in bending resistance as a countermeasure for an increase in surface hardness when applied to a flexible display.

### PRIOR-ART DOCUMENTS

### Patent Documents

Korean Registered Patent No. 10-1241280 (Mar. 4, 2013; AMTE Co., Ltd.)

Korean Registered Patent No. 10-0199406 (Mar. 4, 1999; Hanwha General Chemical Co., Ltd.)

### SUMMARY OF THE INVENTION

The present invention is designed to solve the problems of the prior art, and it is an object of the present invention to provide a hard coating film used as a film for a flexible display window including a touch sensor, which is provided on a window film and thus is capable of driving a touch sensor, preventing dust adhesion, and simultaneously improving surface hardness and bending resistance of the window film, and a flexible display window including a touch sensor using the same.

In addition, it is another object of the present invention to provide a flexible display window including a touch sensor using the above-described hard coating film.

In order to accomplish the above object, a hard coating film according to the present invention has a surface resistance of 5*10¹¹ Ω/sq to 5*10¹³ Ω/sq.

In addition, a display window according to the present invention uses the hard coating film.

As described above, a hard coating film according to the present invention maintains surface resistance at a specific value, and thus a touch sensor can be driven, dust adhesion can be prevented, and excellent surface resistance, pencil hardness and bending resistance can be exhibited.

### DETAILED DESCRIPTION

Hard Coating Film

A hard coating film according to the present invention includes a transparent substrate layer and a hard coating layer, which are sequentially laminated, and has a surface resistance of 5*10¹¹ Ω/sq to 5*10¹³ Ω/sq.

The hard coating film according to the present invention preferably has a surface resistance of 5*10¹¹ Ω/sq to 5*10¹³ Ω/sq. When surface resistance thereof is within the above range, it is possible to prevent dust adhesion without an effect on driving a touch sensor. However, when surface resistance thereof is less than the above range, touch driving may be affected, and when surface resistance thereof is greater than the above range, it is possible to prevent dust adhesion, but an antistatic effect is degraded.

Transparent Substrate Layer

The transparent substrate layer may be any transparent polymer film. The term “transparency” used herein means that the transmittance of visible rays is 70% or more or 80% or more.

The transparent substrate layer may specifically be a film made of a polymer such as triacetyl cellulose, acetyl cellulose butylate, an ethylene/vinyl acetate copolymer, propionyl cellulose, butyryl cellulose, acetylpropionyl cellulose, polyester, polystyrene, polyamide, polyetherimide, polyacryl, polyimide, polyethersulfone, polysulfone, polyethylene, polypropylene, polymethylpentene, polyvinyl chloride, polyvinylidene chloride, polyvinyl alcohol, polyvinyl acetal, polyetherketone, polyether ether ketone, polyethersulfone, polymethyl methacrylate, polyethylene terephthalate, polybutylene terephthalate, polyethylene naphthalate, polycarbonate or the like. These polymers may be used alone or in combination of two or more.

Hard Coating Layer

The hard coating layer may be formed by applying a hard coating composition including lithium ions on one surface of the transparent substrate layer and then photocuring the composition through radiation of ultraviolet rays.

The hard coating composition includes lithium ions, and may further include one or more of a photopolymerizable compound, a solvent and a photoinitiator. This will be described below in more detail.

In this case, a method of applying the hard coating composition may be used without limitation as long as it can be applied in the art. For example, a bar coating method, a knife coating method, a roller coating method, a blade coating method, a die coating method, a micro-gravure coating method, a comma coating method, a slot die coating method, a lip coating method, a solution casting method or the like may be used.

Lithium Ion

A lithium ion may be provided by lithium salts such as lithium perchlorate (LiClO₄), lithium hexafluorophosphate (LiPF₆), lithium hexafluoroarsenate (LiAsF₆) and lithium tetrafluoroborate (LiBF₄), perfluoroalkyl sulfonic-based lithium salts such as lithium trifluoromethanesulfonate (LiTf), lithium bis(trifluoromethane)sulfonimidate (LiTFSI), lithium bis(pentafluoromethane)sulfonimide (LiBETI) and lithium bis(fluorosulfonyl)imide (LiFSI), superacid-based lithium salts (LiSA: CₙF₂ₙ₊₁SO₃Li, n=4,8,10), lithium polyanionic salts, 1,2,3-dithiazolidine-4,4,5,5-tetrafluoro-1,1,3,3-tetraoxide (LiCTFSI), lithium bis(oxalate)borate (LiBOB), imidazole-based lithium salts such as lithium-4,5-dicyano-2-trifluoromethylimidazole (LiTDI) and lithium-4,5-dicyano-2-pentafluoroethylimidazole (LiPDI), non-fluorine-containing lithium salts such as lithium-4,5-dicyano-1,2,3-triazolate (LiDCTA) and lithium tetracyanoborate (LiB(CN)₄), or the like. These may be used alone or in combination of two or more.

Although not limited by theory, it is believed that lithium ions combine with oxygen in a light-transmitting resin to improve the electrical conductivity of a hard coating layer. Also, a flexible ionic bonding site rather than a covalent bond is formed in a hard coating layer. Therefore, it acts like a semi-crosslinked bond to improve hardness upon measurement of hardness and simultaneously the bond is separated freely unlike a covalent bond and a bond is formed again at other sites to improve flexibility upon measurement of flexibility. Therefore, it is considered that hardness and flexibility may be improved at the same time.

In addition, a lithium ion compound is preferably included at 0.1 wt % to 10 wt % with respect to 100 wt % of the entire hard coating composition. when the lithium compound is included at less than 0.1 wt %, dust adhesion prevention performance is degraded due to high surface resistance, and when the lithium compound is included at greater than 10 wt %, touch driving is delayed due to low surface resistance so that normal touch driving is difficult.

Photocurable Resin

The photocurable resin may include a photocurable (meth)acrylate oligomer and monomer.

The photocurable (meth)acrylate oligomer may generally be epoxy (meth)acrylate, urethane (meth)acrylate or the like, and more preferably be urethane (meth)acrylate. The urethane (meth)acrylate may be prepared by reacting a multifunctional (meth)acrylate having a hydroxyl group in a molecule and a compound having an isocyanate group in the presence of a catalyst. Specific examples of the (meth)acrylate having a hydroxyl group in a molecule may be one or more selected from the group consisting of 2-hydroxyethyl (meth)acrylate, 2-hydroxyisopropyl (meth)acrylate, 4-hydroxybutyl (meth)acrylate, caprolactone ring-opened hydroxyacrylate, a mixture of pentaerythritol tri- (or tetra-) (meth)acrylate, and a mixture of dipentaerythritol penta- (or hexa-) (meth)acrylate.

In addition, specific examples of the compound having an isocyanate group may be one or more selected from the group consisting of 1,4-diisocyanatobutane, 1,6-diisocyanatohexane, 1,8-diisocyanatooctane, 1,12-diisocyanatododecane, 1,5-diisocyanato-2-methylpentane, trimethyl-1,6-diisocyanatohexane, 1,3-bis(isocyanatomethyl)cyclohexane, trans-1,4-cyclohexene diisocyanate, 4,4′-methylenebis(cyclohexyl isocyanate), isophorone diisocyanate, toluene-2,4-diisocyanate, toluene-2,6-diisocyanate, xylene-1,4-diisocyanate, tetramethylxylene-1,3-diisocyanate, 1-chloromethyl-2,4-diisocyanate, 4,4′-methylenebis(2,6-dimethylphenyl isocyanate), 4,4′-oxybis(phenyl isocyanate), tri-functional isocyanate derived from hexamethylene diisocyanate, and trimethane propanol adduct toluene diisocyanate.

The photocurable (meth)acrylate monomer has a commonly used photocurable functional group, for example, an unsaturated group such as a (meth)acryloyl group, a vinyl group, a styryl group, an allyl group or the like in a molecule. Among these, the monomer more preferably has a (meth)acryloyl group.

Specific examples of the monomer having a (meth)acryloyl group may be one or more selected from the group consisting of neopentyl glycol acrylate, 1,6-hexanediol (meth)acrylate, propylene glycol di(meth)acrylate, triethylene glycol di(meth)acrylate, dipropylene glycol di(meth)acrylate, polyethylene glycol di(meth)acrylate, polypropylene glycol di(meth)acrylate, trimethylolpropane tri(meth)acrylate, trimethylolethane tri(meth)acrylate, 1,2,4-cyclohexane tetra(meth)acrylate, pentaglycerol tri(meth)acrylate, pentaerythritol tetra(meth)acrylate, pentaerythritol tri(meth)acrylate, dipentaerythritol tri(meth)acrylate, dipentaerythritol penta(meth)acrylate, dipentaerythritol tetra(meth)acrylate, dipentaerythritol hexa(meth)acrylate, tripentaerythritol tri(meth)acrylate, tripentaerythritol hexatri(meth)acrylate, bis(2-hydroxyethyl)isocyanurate di(meth)acrylate, hydroxyethyl (meth)acrylate, hydroxypropyl (meth)acrylate, hydroxybutyl (meth)acrylate, isooctyl (meth)acrylate, iso-decyl (meth)acrylate, stearyl (meth)acrylate, tetrahydrofurfuryl (meth)acrylate, phenoxyethyl (meth)acrylate, and isoborneol (meth)acrylate.

The photocurable resin is preferably included at 1 to 80 parts by weight with respect to 100 parts by weight of the entire hard coating composition, but is not specifically limited thereto. When the photocurable resin is included at less than 1 part by weight, it is difficult to achieve sufficient improvement in hardness, and when the photocurable resin is included at greater than 80 parts by weight, curling increases.

In addition, the photocurable resin may further include an inorganic nanoparticle generally used to reinforce hardness of a hard coating layer. Specifically, when the inorganic nanoparticles are included in the hard coating composition, mechanical properties may be further improved. More specifically, the inorganic nanoparticles are uniformly formed in a coated film, and thus mechanical properties such as abrasion resistance, scratch resistance, pencil hardness and the like may be improved.

The inorganic nanoparticles may have an average diameter of 1 to 100 nm, particularly 1 to 80 nm, and more particularly 5 to 50 nm. When an average diameter of the inorganic nanoparticles is within these ranges, it is possible to prevent a phenomenon in which agglomeration occurs in a composition and thus a uniform coated film is formed, and also prevent a decrease in optical characteristics and mechanical properties of a coated film.

The inorganic nanoparticles may be one or more selected from the group consisting of Al₂O₃, SiO₂, ZnO, ZrO₂, BaTiO₃, TiO₂, Ta₂O₅, Ti₃O₅, ITO, IZO, ATO, ZnO—Al, Nb₂O₃, SnO, MgO and a combination thereof, but the present invention is not limited thereto. The inorganic nanoparticle may include a metal oxide commonly used in the art.

Specifically, the inorganic nanoparticle may be Al₂O₃, SiO₂, or ZrO₂. The inorganic nanoparticle may be directly manufactured or may be a commercially available product in which the inorganic nanoparticles are dispersed in an organic solvent at a concentration of 10 to 80 wt %.

Solvent

The solvent is a material that may dissolve or disperse the above-described composition and may be used without limitation as long as it is known as a solvent of a hard coating composition in the art.

Specifically, the solvent preferably is an alcohol (e.g., methanol, ethanol, isopropanol, butanol, methyl cellosolve, ethyl cellosolve, and the like), a ketone (e.g., methyl ethyl ketone, methyl butyl ketone, methyl isobutyl ketone, diethyl ketone, dipropyl ketone, cyclohexanone, and the like), an acetate (e.g., ethyl acetate, propyl acetate, n-butyl acetate, t-butyl acetate, methyl cellosolve acetate, ethyl cellosolve acetate, propylene glycol monomethyl ether acetate, propylene glycol monoethyl ether acetate, propylene glycol monopropyl ether acetate, methoxybutyl acetate, methoxypentyl acetate, and the like), an alkane (e.g., hexane, heptane, octane, and the like), benzene or derivatives thereof (e.g., benzene, toluene, xylene, and the like), ethers (e.g., diethylene glycol dimethyl ether, diethylene glycol diethyl ether, diethylene glycol dipropyl ether, diethylene glycol dibutyl ether, propylene glycol monomethyl ether, and the like), or the like. The solvents may be used alone or in combination of two or more.

The solvent is preferably included at 10 to 95 wt % with respect to 100 wt % of the entire hard coating composition. When a content of the solvent is less than 10 wt %, not only workability may be degraded due to an increase in viscosity but also the swelling of the transparent substrate layer may not be sufficiently advanced. On the other hand, when a content of the solvent is greater than 95 wt %, a drying process may take a long time and economic feasibility may decrease.

Photoinitiator

The photoinitiator may be used without limitation as long as it is used in the art, and may be one or more selected from the group consisting of a hydroxy ketone, an amino ketone, a hydrogen-abstraction-type photoinitiator and a combination thereof.

Specifically, the photoinitiator may be one or more selected from the group consisting of 2-methyl-1-[4-(methylthio)phenyl]2-morpholine propanone-1, diphenyl ketone, benzyl dimethyl ketal, 2-hydroxy-2-methyl-1-phenyl-1-one, 4-hydroxy cyclophenyl ketone, 2,2-dimethoxy-2-phenyl-acetophenone, anthraquinone, fluorene, triphenylamine, carbazole, 3-methylacetophenone, 4-chloroacetophenone, 4,4-dimethoxyacetophenone, 4,4-diaminobenzophenone, 1-hydroxycyclohexyl phenyl ketone, benzophenone, diphenyl(2,4,6-trimethylbenzoyl)phosphine oxide and a combination thereof.

The photoinitiator is preferably included at 0.1 to 10 wt %, more preferably, 1 to 5 wt % with respect to 100 wt % of the entire hard coating composition. When a content of the photoinitiator is less than 0.1 wt %, the curing speed of the hard coating composition may decrease and mechanical properties may be degraded due to insufficient curing caused by a decrease in the curing speed. On the other hand, when a content thereof is greater than 10 wt %, a coated film may be cracked due to overcuring.

The hard coating film according to the present invention preferably has a pencil hardness of 5 H or higher, and more preferably 6 H or higher. When the hard coating film has a pencil hardness in the above range, excellent surface hardness may be realized.

Display Window

The present invention provides a display window using a hard coating film. In this case, the display window may be flexible. Specifically, the hard coating film may be used as a functional layer or a substitute for a cover glass of a display such as a LCD, an OLED, a LED, a FED and the like, a touch panel of various mobile communication terminals, a smart phone or a tablet PC using the display, electronic paper or the like.

The present invention provides an image display device including the display window, and the image display device may be a touch sensor.

Hereinafter, the present invention will be described in more detail with reference to the exemplary embodiments. However, the exemplary embodiments should be considered in a descriptive sense only, and the present invention is not limited thereto. Therefore, it should be understood that various changes and modifications can be made to the exemplary embodiments without departing from the scope of the present invention by those skilled in the art. Hereinafter, all “percentage(s)” and “part(s)” representing the content are by weight unless otherwise specified.

### EXEMPLIFICATION

### Preparation Examples 1-5: Preparation of Hard Coating Composition

### Preparation Example 1

20 parts by weight of urethane acrylate (deca-functional acrylate; Miramer MU9500 commercially available from Miwon Specialty Chemical Co., Ltd.), 20 parts by weight of an ethylene-oxide-containing multifunctional acrylate (tri-functional acrylate; Miramer M3160 commercially available from Miwon Specialty Chemical Co., Ltd.), 20 parts by weight of a nanosilica sol (12 nm; a solid content of 40%), 2 parts by weight of lithium perchlorate (LiClO₄), 35 parts by weight of propylene glycol monomethyl ether, 2.5 parts by weight of a photoinitiator (1-Hydroxy-cyclohexyl-phenyl-ketone) and 0.5 parts by weight of a leveling agent (BYK3570 commercially available from BYK Chemie Gmbh) were mixed using a stirrer and filtered using a filter made of polypropylene (PP) to prepare a hard coating composition.

### Preparation Example 2

20 parts by weight of urethane acrylate (deca-functional acrylate; Miramer MU9500 commercially available from Miwon Specialty Chemical Co., Ltd.), 20 parts by weight of an ethylene-oxide-containing multifunctional acrylate (tri-functional acrylate; Miramer M3160 commercially available from Miwon Specialty Chemical Co., Ltd.), 20 parts by weight of a nanosilica sol (12 nm; a solid content of 40%), 2 parts by weight of lithium hexafluorophosphate (LiPF₆), 35 parts by weight of propylene glycol monomethyl ether, 2.5 parts by weight of a photoinitiator (1-Hydroxy-cyclohexyl-phenyl-ketone) and 0.5 parts by weight of a leveling agent (BYK3570 commercially available from BYK Chemie Gmbh) were mixed using a stirrer and filtered using a filter made of polypropylene (PP) to prepare a hard coating composition.

### Preparation Example 3

20 parts by weight of urethane acrylate (deca-functional acrylate; Miramer MU9500 commercially available from Miwon Specialty Chemical Co., Ltd.), 20 parts by weight of an ethylene-oxide-containing multifunctional acrylate (tri-functional acrylate; Miramer M3160 commercially available from Miwon Specialty Chemical Co., Ltd.), 20 parts by weight of a nanosilica sol (12 nm; a solid content of 40%), 2 parts by weight of lithium bis(fluorosulfonyl)imide (LiFSI), 35 parts by weight of propylene glycol monomethyl ether, 2.5 parts by weight of a photoinitiator (1-Hydroxy-cyclohexyl-phenyl-ketone) and 0.5 parts by weight of a leveling agent (BYK3570 commercially available from BYK Chemie Gmbh) were mixed using a stirrer and filtered using a filter made of polypropylene (PP) to prepare a hard coating composition.

### Preparation Example 4

20 parts by weight of urethane acrylate (deca-functional acrylate; Miramer MU9500 commercially available from Miwon Specialty Chemical Co., Ltd.), 20 parts by weight of an ethylene-oxide-containing multifunctional acrylate (tri-functional acrylate; Miramer M3160 commercially available from Miwon Specialty Chemical Co., Ltd.), 20 parts by weight of a nanosilica sol (12 nm; a solid content of 40%), 2 parts by weight of lithium bis(trifluoromethane)sulfonimidate (LiTFSI), 35 parts by weight of propylene glycol monomethyl ether, 2.5 parts by weight of a photoinitiator (1-Hydroxy-cyclohexyl-phenyl-ketone) and 0.5 parts by weight of a leveling agent (BYK3570 commercially available from BYK Chemie Gmbh) were mixed using a stirrer and filtered using a filter made of polypropylene (PP) to prepare a hard coating composition.

### Preparation Example 5

20 parts by weight of urethane acrylate (deca-functional acrylate; Miramer MU9500 commercially available from Miwon Specialty Chemical Co., Ltd.), 20 parts by weight of an ethylene-oxide-containing multifunctional acrylate (tri-functional acrylate; Miramer M3160 commercially available from Miwon Specialty Chemical Co., Ltd.), 20 parts by weight of a nanosilica sol (12 nm; a solid content of 40%), 37 parts by weight of propylene glycol monomethyl ether, 2.5 parts by weight of a photoinitiator (1-Hydroxy-cyclohexyl-phenyl-ketone) and 0.5 parts by weight of a leveling agent (BYK3570 commercially available from BYK Chemie Gmbh) were mixed using a stirrer and filtered using a filter made of polypropylene (PP) to prepare a hard coating composition.

### Examples 1-4 and Comparative Example 1: Manufacture of Hard Coating Film

### Example 1

The hard coating composition (hard coating solution) prepared in Preparation Example 1 was applied on one surface of a polyimide film having a thickness of 50 μm in such a way that the composition has a thickness of 10 μm after curing. After coating the film, the solvent was dried and UV rays were radiated at an integrated light intensity of 500 mJ/cm² for coating one surface. Afterward, the hard coating composition prepared in Preparation Example 1 was applied on the other surface of the polyimide film in such a way that the composition has a thickness of 10 μm after curing. After coating the film, the solvent was dried and UV rays were radiated to manufacture a hard coating film.

### Example 2

A hard coating film was manufactured in the same manner as in Example 1 except that the hard coating composition prepared in Preparation Example 2 was used instead of that of Preparation Example 1.

### Example 3

A hard coating film was manufactured in the same manner as in Example 1 except that the hard coating composition prepared in Preparation Example 3 was used instead of that of Preparation Example 1.

### Example 4

A hard coating film was manufactured in the same manner as in Example 1 except that the hard coating composition prepared in Preparation Example 4 was used instead of that of Preparation Example 1.

### Comparative Example 1

A hard coating film was manufactured in the same manner as in Example 1 except that the hard coating composition prepared in Preparation Example 5 was used instead of that of Preparation Example 1.

### Experimental Example

Properties of the hard coating films prepared in Examples 1 to 4 and Comparative Example 1 were measured in the following manner, results of which are shown in Table 1. A measurement method and an evaluation method used in the present invention are as follows.

1) Surface Resistance

A voltage of 500 V was applied to a surface of a hard coating film to measure surface resistance using a URS probe of a high resistivity meter (Hiresta-UP, MCP-HT450 commercially available from Mitsubishi Chemical Analytech Co., Ltd.). The results are shown in the following Table 1.

2) Pencil Hardness

After a pencil was set in a direction of a 45 degree angle under a load of 1 kg, a coating film was fixed on glass. Afterward, the evaluation was performed five times using a pencil having each pencil hardness, and then pencil hardness was indicated by the hardness value of the pencil which does not mark the coating film four times or more. The results are shown in the following Table 1.

3) Bending Resistance

A coating layer of a hard coating film is directed to face inward, and a hard coating film was folded in half to have an interval of 6 mm between surfaces thereof. Afterward, whether or not a folded portion was cracked when the film was unfolded again was observed by the naked eye and evaluated. The results are shown in the following Table 1.

Good: no cracking at folded portion

Failure: cracking at folded portion

TABLE 1

| | Surface resistance | Pencil hardness | Bending resistance |
|---|---|---|---|
| Example 1 | 1.1*10¹² Ω/sq | 6 H | Good |
| Example 2 | 4.2*10¹² Ω/sq | 6 H | Good |
| Example 3 | 6.2*10¹² Ω/sq | 6 H | Good |
| Example 4 | 3.7*10¹² Ω/sq | 6 H | Good |
| Comparative | 1*10¹⁴ Ω/sq or more | 4 H | Failure |
| Example 1 | (over) | | |

Referring to Table 1, it can be seen that excellent surface resistance, pencil hardness and bending resistance were exhibited in the case of Examples 1 to 4 of the present invention. In particular, the hard coating film may realize a pencil hardness of 6 H or more. Therefore, since the hard coating film has the above pencil hardness, excellent surface hardness may be implemented.

On the other hand, it can be seen that surface resistance exceeded a mechanical measurement range and pencil hardness and bending resistance also were not excellent in the case of Comparative Example 1.

What is claimed is:

1. A hard coating film used as a film for a flexible display window comprising a touch sensor, wherein the hard coating film has a surface resistance of 5*10¹¹ Ω/sq to 5*10¹³ Ω/sq.

2. The hard coating film according to claim 1, wherein the hard coating film has a pencil hardness of 5H or higher.

3. The hard coating film according to claim 1, wherein the hard coating film comprises a cured product of a hard coating composition comprising a lithium ion compound.

4. The hard coating film according to claim 3, wherein the lithium ion compound is included at a content of 0.1 to 10 wt % with respect to 100 wt % of the entire hard coating composition.

5. The hard coating film according to claim 3, wherein the hard coating composition further comprises one or more selected from the group consisting of a photocurable resin, a solvent and a photoinitiator.

6. The hard coating film according to claim 3, wherein the hard coating composition further comprises an inorganic nanoparticle.

7. The hard coating film according to claim 5, wherein the photocurable resin is 1 to 80 parts by weight with respect to 100 parts by weight of the entire hard coating composition.

8. The hard coating film according to claim 5, wherein the solvent is 10 to 95 wt % with respect to 100 wt % of the entire hard coating composition.

9. The hard coating film according to claim 5, wherein the photoinitiator is 0.1 to 10 wt % with respect to 100 wt % of the entire hard coating composition.

10. A flexible display window comprising a touch sensor using the hard coating film according to claim 1.

11. An image display device having the flexible display window including a touch sensor according to claim 10.
